(19) United States
(12) Patent Application Publication
(10) Pub. No.: US 2023/0045660 A1
(43) Pub. Date: Feb. 9, 2023

(54) NITRIDE SEMICONDUCTOR DEVICE

(71) Applicant: ROHM CO., LTD., Kyoto-shi, Kyoto (JP)

(72) Inventor: Hirotaka OTAKE, Kyoto-shi, Kyoto (JP)

(73) Assignee: ROHM CO., LTD., Kyoto-shi, Kyoto (JP)

(21) Appl. No.: 17/789,786

(22) PCT Filed: Jan. 15, 2021
(86) PCT No.: PCT/JP2021/001166

§ 371 Date: Jun. 29, 2022

(30) Foreign Application Priority Data
Jan. 28, 2020 (JP) 2020-011740

(51) Int. Cl. H01L 29/66; H01L 29/20; H01L 29/778; H01L 29/423; H01L 29/417

(52) U.S. Cl. CPC H01L 29/66462; H01L 29/2003; H01L 29/7786; H01L 29/42316; H01L 29/41758

(57) ABSTRACT

A nitride semiconductor device includes a first nitride semiconductor layer, a second nitride semiconductor layer formed on the first nitride semiconductor layer, a third nitride semiconductor layer that is disposed on the second nitride semiconductor layer, has a ridge portion at least at a portion thereof, and contains an acceptor type impurity, a gate electrode that is disposed on the ridge portion, and a source electrode and a drain electrode that, on the second nitride semiconductor layer, are disposed across the ridge portion from each other, and has an active region and a nonactive region. The nonactive region has a first region and a film thickness of the second nitride semiconductor layer in the first region differs from a film thickness of the second nitride semiconductor layer in a region of the active region in which the ridge portion, the source electrode, and the drain electrode are not formed.

### TECHNICAL FIELD

The present invention relates to a nitride semiconductor device that is constituted of a group III nitride semiconductor (hereinafter referred to at times simply as “nitride semiconductor”).

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples thereof. A group III nitride semiconductor can generally be expressed as AlₓIn_{y}Ga_{1-x-y}N (0≤x≤1, 0≤y≤1, 0≤x+y≤1).

An HEMT (high electron mobility transistor) using such a nitride semiconductor has been proposed. Such an HEMT includes, for example, an electron transit layer constituted of GaN and an electron supply layer constituted of AlGaN epitaxially grown on the electron transit layer. A pair of source electrode and drain electrode are formed such as to contact the electron supply layer and a gate electrode is disposed therebetween.

Due to polarization caused by lattice mismatch of GaN and AlGaN, a two-dimensional electron gas is formed at a position inside the electron transit layer that is only a few A inward from an interface between the electron transit layer and the electron supply layer. A source and a drain are connected to each other with the two-dimensional electron gas as a channel. When the two-dimensional electron gas is interrupted by application of a control voltage to the gate electrode, the source and the drain are interrupted from each other. The source and the drain are made conductive to each other in a state where the control voltage is not applied to the gate electrode and therefore the device is of a normally-on type.

Devices using a nitride semiconductor have features of high withstand voltage, high temperature operation, high current density, high speed switching, and low on resistance and applications to power devices are thus being proposed, for example, in Patent Literature 1.

Patent Literature 1 discloses an arrangement where a p type GaN gate layer of a ridge shape (corresponding to a ridge portion of a third nitride semiconductor layer of the present invention) is laminated on an AlGaN electron supply layer, a gate electrode is disposed thereon, and a channel is eliminated by a depletion layer spreading from the p type GaN gate layer to achieve a normally-off operation.

Also, with Patent Literature 2, in order to achieve the normally-off operation using a p type GaN gate layer, a high-concentration p type GaN layer and a gate electrode are put in ohmic connection. Due to the ohmic connection, the arrangement is an ohmic GIT (gate injection transistor) with which conductivity modulation is intended to be performed by making a current flow through the gate electrode and implanting holes into the high-concentration p type GaN layer from the gate electrode.

### CITATION LIST

### Patent Literature

Patent Literature 1: Japanese Patent Application Publication No. 2017-73506
Patent Literature 2: Japanese Patent Application Publication No. 2006-339561

### SUMMARY OF INVENTION

### Technical Problem

An object of the present invention is to provide a nitride semiconductor device that enables a film thickness of a material film of a third nitride semiconductor layer to be directly measured before forming a ridge portion of the third nitride semiconductor layer and a method for manufacturing the nitride semiconductor device.

### Solution to Problem

A preferred embodiment of the present invention provides a nitride semiconductor device including a substrate, a first nitride semiconductor layer that is disposed above the substrate and constitutes an electron transit layer, a second nitride semiconductor layer that is formed on the first nitride semiconductor layer and constitutes an electron supply layer, a third nitride semiconductor layer that is disposed on the second nitride semiconductor layer, has a ridge portion at least at a portion thereof, and contains an acceptor type impurity, a gate electrode that is disposed on the ridge portion, and a source electrode and a drain electrode that, on the second nitride semiconductor layer, are disposed across the ridge portion from each other, and having, in plan view, an active region that contributes to a transistor operation and a nonactive region that does not contribute to the transistor operation, and where the nonactive region has a first region and a film thickness of the second nitride semiconductor layer in the first region differs from a film thickness of the second nitride semiconductor layer in a region of the active region in which the ridge portion, the source electrode, and the drain electrode are not formed.

With the present arrangement, it is possible to directly measure a film thickness of a material film of the third nitride semiconductor layer in the first region before forming the ridge portion of the third nitride semiconductor layer.

In the preferred embodiment of the present invention, the film thickness of the second nitride semiconductor layer in the first region is thicker than the film thickness of the second nitride semiconductor layer in the region of the active region in which the ridge portion, the source electrode, and the drain electrode are not formed.

In the preferred embodiment of the present invention, the film thickness of the second nitride semiconductor layer in the first region is thinner than the film thickness of the second nitride semiconductor layer in the region of the active region in which the ridge portion, the source electrode, and the drain electrode are not formed.

In the preferred embodiment of the present invention, the first region is adjacent to the third nitride semiconductor layer.

In the preferred embodiment of the present invention, the nitride semiconductor device has a quadrilateral shape in plan view and the first region is present between a peripheral edge of the nitride semiconductor device and the active region in plan view.

In the preferred embodiment of the present invention, the third nitride semiconductor layer has an extension region that extends from an end of the ridge portion, an opening portion that penetrates through the gate electrode and the third nitride semiconductor layer and reaches the second nitride semiconductor layer is formed inside the extension region within the nonactive region, and the first region is, in plan view, a region in which the opening portion is formed.

In the preferred embodiment of the present invention, in plan view, a side edge at the first region side of the gate electrode on the ridge portion adjacent to the first region is receded further inward than a side edge at the first region side of an upper surface of the ridge portion.

In the preferred embodiment of the present invention, a passivation film that covers exposed surfaces of the second nitride semiconductor layer, the third nitride semiconductor layer, and the gate electrode is formed on the second nitride semiconductor layer, a source contact hole and a drain contact hole are formed in the passivation film, the source electrode penetrates through the source contact hole and contacts the second nitride semiconductor layer, and the drain electrode penetrates through the drain contact hole and contacts the second nitride semiconductor layer.

In the preferred embodiment of the present invention, the source electrode has a source main electrode portion that penetrates through the source contact hole and contacts the second nitride semiconductor layer and an extension portion that extends from the source main electrode portion and covers the gate electrode adjacent thereto.

In the preferred embodiment of the present invention, the source main electrode portion extends in parallel to the ridge portion and a source electrode recess that extends in a length direction of the source main electrode portion is formed in a width intermediate portion of a front surface of the source main electrode portion.

In the preferred embodiment of the present invention, the drain electrode extends in parallel to the ridge portion and a drain electrode recess that extends in a length direction of the drain electrode is formed in a width intermediate portion of a front surface of the drain electrode.

In the preferred embodiment of the present invention, a first recess that penetrates through the passivation film and the second nitride semiconductor layer, reaches the first nitride semiconductor layer, and is opened at its upper surface and outer side surface is formed in a peripheral edge portion of the nitride semiconductor device and a second recess that penetrates through the first nitride semiconductor layer, reaches the substrate, and is opened at its upper surface and outer side surface is formed in an outer peripheral edge portion of a bottom surface of the first recess.

In the preferred embodiment of the present invention, a film thickness of the third nitride semiconductor layer is greater than 100 nm.

In the preferred embodiment of the present invention, the gate electrode is constituted of a single film of any one among TiN, TiW, Ti, and W or a composite film of any combination of two or more thereamong.

In the preferred embodiment of the present invention, the second nitride semiconductor layer is constituted of an AlₓGa₁₋ₓN (0<x1<1) layer and the second nitride semiconductor layer is constituted of a GaN layer.

In the preferred embodiment of the present invention, the acceptor impurity is Mg, Zn, or a codope thereof.

A preferred embodiment of the present invention provides a method for manufacturing nitride semiconductor device including a step of preparing a nitride semiconductor laminated structure that includes a substrate, a first nitride semiconductor layer disposed above the substrate and constituting an electron transit layer, a second nitride semiconductor layer formed on the first nitride semiconductor layer and constituting an electron supply layer, and a third nitride semiconductor layer disposed on the second nitride semiconductor layer and containing an acceptor type impurity, a step of forming a gate electrode film on the nitride semiconductor laminated structure, a first etching step of selectively etching the gate electrode film and the third nitride semiconductor layer to form an opening region that penetrates through the gate electrode film and the third nitride semiconductor layer and reaches the second nitride semiconductor layer, and a second etching step of selectively etching the gate electrode film and the third nitride semiconductor layer after the first etching step to form a gate electrode portion of a ridge shape on the second nitride semiconductor layer and where etching conditions of the first etching step and the second etching step differ.

With this manufacturing method, it is possible to directly measure a film thickness of a material film of the third nitride semiconductor layer after the first etching step. It is thereby made possible to directly measure the film thickness of the material film of the third nitride semiconductor layer before forming a ridge portion of the third nitride semiconductor layer.

In the preferred embodiment of the present invention, the film thickness of the third nitride semiconductor layer is measured using the opening region and the etching condition of the second etching step is determined based on the measurement result.

In the preferred embodiment of the present invention, the first etching step also serves as an alignment forming step.

In the preferred embodiment of the present invention, the first etching step is constituted of a third etching step of etching the gate electrode film and a fourth etching step of etching the third nitride semiconductor layer, the second etching step is constituted of a fifth etching step of etching the gate electrode film and a sixth etching step of etching the third nitride semiconductor layer, etching conditions of the third etching step and the fourth etching step differ mutually, and etching conditions of the fifth etching step and the sixth etching step differ mutually.

In the preferred embodiment of the present invention, the etching conditions of the fourth etching step and the sixth etching step differ mutually.

In the preferred embodiment of the present invention, the etching conditions of the third etching step and the fifth etching step are the same.

In the preferred embodiment of the present invention, the first etching step has a step for making a peripheral edge of the gate electrode film along the opening region recede further toward an outer side of the opening region than a peripheral edge of the third nitride semiconductor layer along the opening region.

In the preferred embodiment of the present invention, in the first etching step, the opening region is formed in an entirety of a peripheral edge portion of the gate electrode film. In this case, there may be included, between the first etching step and the second etching step, a step of forming an insulating film on an entire surface after a film thickness measurement of the third nitride semiconductor layer using the opening region has been performed and a step of selectively forming a resist film on the insulating film such as to cover a gate electrode preparation planned region and a region further outward than the gate electrode preparation planned region in plan view.

In the preferred embodiment of the present invention, the gate electrode film has a quadrilateral shape in plan view and, in the first etching step, the opening region is formed at a position close to a corner of the gate electrode film. In this case, there may be included, between the first etching step and the second etching step, a step of forming an insulating film on an entire surface after a film thickness measurement of the third nitride semiconductor layer using the opening region has been performed and a step of selectively forming a resist film on the insulating film such as to cover a gate electrode preparation planned region in plan view.

The aforementioned as well as yet other objects, features, and effects of the present invention will be made clear by the following description of the preferred embodiments made with reference to the accompanying drawings.

### BRIEF DESCRIPTION OF DRAWINGS

FIG. 1 is a plan view for describing the arrangement of a nitride semiconductor device according to a first preferred embodiment of the present invention.

FIG. 2 is an enlarged sectional view taken along line II-II of FIG. 1.

FIG. 3A is a sectional view of an example of a manufacturing process of the nitride semiconductor device of FIG. 1.

FIG. 3B is a sectional view of a step subsequent to that of FIG. 3A.

FIG. 3C is a sectional view of a step subsequent to that of FIG. 3B.

FIG. 3D is a sectional view of a step subsequent to that of FIG. 3C.

FIG. 3E is a sectional view of a step subsequent to that of FIG. 3D.

FIG. 3F is a sectional view of a step subsequent to that of FIG. 3E.

FIG. 3G is a sectional view of a step subsequent to that of FIG. 3F.

FIG. 3H is a sectional view of a step subsequent to that of FIG. 3G.

FIG. 3I is a sectional view of a step subsequent to that of FIG. 3H.

FIG. 3J is a sectional view of a step subsequent to that of FIG. 3I.

FIG. 3K is a sectional view of a step subsequent to that of FIG. 3J.

FIG. 3L is a sectional view of a step subsequent to that of FIG. 3K.

FIG. 3M is a sectional view of a step subsequent to that of FIG. 3L.

FIG. 3N is a sectional view of a step subsequent to that of FIG. 3M.

FIG. 3O is a sectional view of a step subsequent to that of FIG. 3N.

FIG. 3P is a sectional view of a step subsequent to that of FIG. 3O.

FIG. 3Q is a sectional view of a step subsequent to that of FIG. 3P.

FIG. 3R is a sectional view of a step subsequent to that of FIG. 3Q.

FIG. 3S is a sectional view of a step subsequent to that of FIG. 3R.

FIG. 4 is a sectional view for describing a modification example of the manufacturing process of the nitride semiconductor device of FIG. 1.

FIG. 5 is a plan view for describing the arrangement of a nitride semiconductor device according to a second preferred embodiment of the present invention.

FIG. 6 is an enlarged sectional view taken along line VI-VI of FIG. 5.

### DESCRIPTION OF EMBODIMENTS

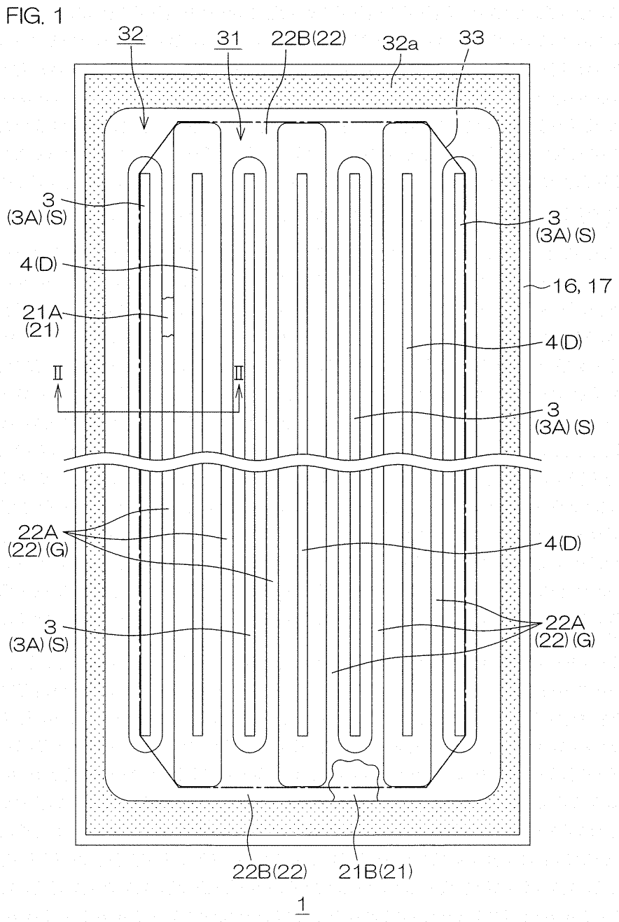

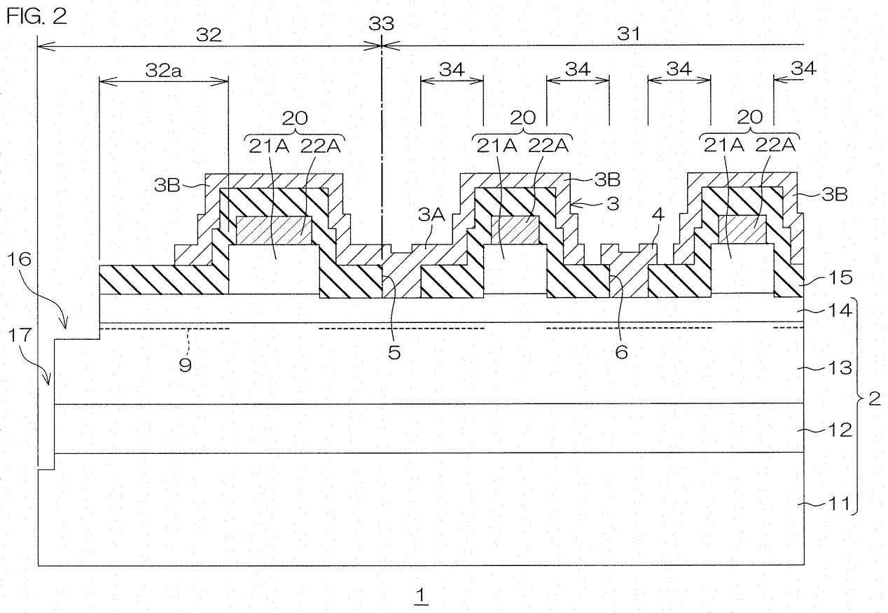

FIG. 1 is a plan view for describing the arrangement of a nitride semiconductor device according to a first preferred embodiment of the present invention. FIG. 2 is an enlarged sectional view taken along line II-II of FIG. 1.

However, in FIG. 1, a passivation film 15 (see FIG. 2) is omitted for convenience of description. Also, in FIG. 1, just a source main electrode portion 3A is illustrated for each source electrode 3 and an extension portion 3B is omitted. Also, although a width of each ridge portion 21A of a third nitride semiconductor layer 21 is greater than a width of each gate main electrode portion 22A of a gate electrode 22 as shall be described below, the width of each ridge portion 21A is illustrated as being equal to the width of each gate main electrode portion 22A in FIG. 1.

For convenience of description, a right-left direction of the paper surface of FIG. 1 shall be referred to at times as the lateral direction and an up-down direction of the paper surface of FIG. 1 shall be referred to at times as the longitudinal direction in the following description.

The nitride semiconductor device 1 has, in plan view, a quadrilateral shape having two sides parallel to the lateral direction and two sides parallel to the longitudinal direction. The nitride semiconductor device 1 has a semiconductor laminated structure 2 (see FIG. 2) and an electrode metal structure disposed on the semiconductor laminated structure 2.

As shown in FIG. 1, the electrode metal structure includes a plurality of the source electrodes 3, the gate electrode 22, and a plurality of drain electrodes 4. The source electrodes 3 and the drain electrodes 4 extend in the longitudinal direction.

The gate electrode 22 includes a plurality of the gate main electrode portions 22A that extend in parallel to each other in the longitudinal direction and two base portions 22B that respectively couple corresponding end portions of the gate main electrode portions 22A to each other.

In plan view, each source electrode 3 is constituted of a source main electrode portion 3A that is disposed between two adjacent gate main electrode portions 22A and an extension portion 3B (see FIG. 2) at a periphery of the source main electrode portion 3A. In this preferred embodiment, the source main electrode portion 3A shall refer to a region, among an entire region of the source electrode 3, that is constituted of a region surrounded by an outline of a source contact hole 5 and a peripheral region thereof in plan view. The extension portion 3B refers to a portion, among the entire region of the source electrode 3, other than the source main electrode portion 3A in plan view. As shown in FIG. 2, the extension portion 3B covers the pair of gate main electrode portions 22A that are disposed at both sides of the source main electrode portion 3A.

A drain electrode 4 is disposed at each of both sides of each source electrode 3. A drain electrode 4 and a source main electrode portion 3A that are adjacent to each other oppose each other across a gate main electrode portion 22A in plan view. In this preferred embodiment, a length of each drain electrode 4 and a length of each source main electrode portion 3A are substantially equal and longitudinal direction positions of both ends of the drain electrode 4 and longitudinal direction positions of corresponding ends of the source main electrode portion 3A are substantially matched.

In the example of FIG. 1, the source main electrode portions 3A (S), the gate main electrode portions 22A (G), and the drain electrodes 4 (D) are disposed periodically in the order of DGSGDGS in the lateral direction. An element structure is thereby arranged by each gate main electrode portion 22A (G) being sandwiched by a source main electrode portion 3A (S) and a drain electrode 4 (D).

A region of a front surface on the semiconductor laminated structure 2 is constituted of an active region 31 that contributes to a transistor operation and a nonactive region 32 that does not contribute to the transistor operation. In FIG. 1 and FIG. 2, alternate long and short dashed lines 33 indicate boundary lines between the active region 31 and the nonactive region 32. In this preferred embodiment, the active region 31 shall refer to a region in which a current flows between a source and a drain when an on voltage is applied to the gate electrode 22.

As shown in FIG. 2, the semiconductor laminated structure 2 includes a substrate 11, a buffer layer 12 that is formed on a front surface of the substrate 11, a first nitride semiconductor layer 13 that is epitaxially grown on the buffer layer 12 and a second nitride semiconductor layer 14 that is epitaxially grown on the first nitride semiconductor layer 13.

The substrate 11 may, for example, be a silicon substrate of low resistance. The silicon substrate of low resistance may be a p type substrate having an electric resistivity of, for example, 0.001 Ωmm to 0.5 Ωmm (more specifically, approximately 0.01 Ωmm to 0.1 Ωmm)). Also, besides a silicon substrate of low resistance, the substrate 11 may instead be an SiC substrate of low resistance, a GaN substrate of low resistance, etc. Also, the substrate 11 may be an insulating substrate such as a sapphire substrate, etc. The substrate 11 has a thickness, for example, of approximately 650 μm during a semiconductor process and is ground to not more than approximately 300 μm in a preliminary stage before being made into a chip. The substrate 11 is electrically connected to the source electrodes 3.

In this preferred embodiment, the buffer layer 12 is constituted of a multilayer buffer layer in which a plurality of nitride semiconductor films are laminated. In this preferred embodiment, the buffer layer 12 is constituted of a first buffer layer (not shown) constituted of an AlN film in contact with the front surface of the substrate 11 and a second buffer layer (not shown) constituted of an AlN/AlGaN superlattice layer laminated on a front surface of the first buffer layer (front surface at an opposite side to a substrate 11 side). A film thickness of the first buffer layer is approximately 100 nm to 500 nm. A film thickness of the second buffer layer is approximately 500 nm to 2 μm. The buffer layer 12 may instead be constituted, for example, of a single film or a composite film of AlGaN.

In addition, an impurity may be introduced to make the buffer layer 12 semi-insulating. In this case, a concentration of the impurity is preferably not less than 4×10¹⁶ cm⁻³. Also, the impurity is, for example, Fe (iron).

The first nitride semiconductor layer 13 constitutes an electron transit layer. The first nitride semiconductor layer 13 is constituted of a GaN layer and a thickness thereof is approximately 0.5 μm to 2 μm. Also, an impurity by which a region of the first nitride semiconductor layer 13 other than a surface layer portion is made semi-insulating may be introduced for a purpose of suppressing a leak current that flows via the first nitride semiconductor layer 13. In this case, a concentration of the impurity is preferably not less than 1×10¹⁷ cm⁻³. Also, the impurity is, for example, C (carbon).

The second nitride semiconductor layer 14 constitutes an electron supply layer. The second nitride semiconductor layer 14 is constituted of a nitride semiconductor with a larger bandgap than the first nitride semiconductor layer 13. In this preferred embodiment, the second nitride semiconductor layer 14 is constituted of a nitride semiconductor with a higher Al composition than the first nitride semiconductor layer 13. In a nitride semiconductor, the higher the Al composition, the larger the bandgap. In this preferred embodiment, the second nitride semiconductor layer 14 is constituted of an Alₓ₁Ga₁₋ₓ₁N layer (0<x1<1) and a thickness thereof is approximately 5 nm to 25 nm.

The first nitride semiconductor layer (electron transit layer) 13 and the second nitride semiconductor layer (electron supply layer) 14 are thus constituted of nitride semiconductors that differ in bandgap (Al composition) and a lattice mismatch occurs therebetween. Also, due to spontaneous polarizations of the first nitride semiconductor layer 13 and the second nitride semiconductor layer 14 and a piezo polarization due to the lattice mismatch between the two, an energy level of a conduction band of the first nitride semiconductor layer 13 at an interface between the first nitride semiconductor layer 13 and the second nitride semiconductor layer 14 is made lower than a Fermi level. Thereby, inside the surface layer portion of the first nitride semiconductor layer 13, a two-dimensional electron gas 9 spreads at a position close to the interface between the first nitride semiconductor layer 13 and the second nitride semiconductor layer 14 (for example, at a distance of only several A from the interface).

The third nitride semiconductor layer (semiconductor gate layer) 21 is interposed between the second nitride semiconductor layer 14 and the gate electrode 22. The third nitride semiconductor layer 21 is formed by epitaxial growth on the front surface of the second nitride semiconductor layer 14. The third nitride semiconductor layer 21 has substantially the same shape as the gate electrode 22 in plan view. Specifically, the third nitride semiconductor layer 21 includes a plurality of ridge portions 21A that extend in parallel to each other in the longitudinal direction and two coupling portions 21B (see FIG. 1) that respectively couple corresponding end portions of the ridge portions 21A to each other.

The gate electrode 22 is formed on the third nitride semiconductor layer 21. More specifically, a gate main electrode portion 22A of the gate electrode 22 is formed on each of the ridge portions 21A of the third nitride semiconductor layer 21. A base portion 22B of the gate electrode 22 is formed on each of the two coupling portions 21B of the third nitride semiconductor layer 21. Gate portions 20 of ridge shape are each formed by a ridge portion 21A of the third nitride semiconductor layer 21 and the gate main electrode portion 22A formed thereon.

Here, the gate portion 20 that is constituted of the ridge portion 21A at the leftmost side of FIG. 2 and the gate main electrode portion 22A thereon functions as a guard link and does not contribute to the transistor operation. The gate portion 20 that is constituted of the ridge portion 21A at the rightmost side of FIG. 2 and the gate main electrode portion 22A thereon also functions as a guard link and does not contribute to the transistor operation.

Lateral cross sections of the ridge portions 21A and the gate main electrode portions 22A are of rectangular shapes. A width of each gate main electrode portion 22A is narrower than a width of each ridge portion 21A. The gate main electrode portion 22A is formed on a width intermediate portion of an upper surface of the ridge portion 21A. Therefore, a step is formed between the upper surface of the gate main electrode portion 22A and the upper surface at one side portion of the ridge portion 21A and a step is formed between the upper surface of the gate main electrode portion 22A and the upper surface at the other side portion of the ridge portion 21A. Also, in plan view, both side edges of the gate main electrode portion 22A are receded further inward than corresponding side edges of the ridge portion 21A.

In this preferred embodiment, the gate electrode 22 is in Schottky contact with an upper surface of the third nitride semiconductor layer 21. The gate electrode 22 is constituted of TiN. A film thickness of the gate electrode 22 is approximately 50 nm to 150 nm. The gate electrode 22 may be constituted of a single film that is any one of a Ti film, a TiN film, a TiW film, and W film or of a composite film constituted of any combination of two or more of the films.

The third nitride semiconductor layer 21 is constituted of a nitride semiconductor that is doped with an acceptor type impurity. In this preferred embodiment, the third nitride semiconductor layer 21 is constituted of a GaN layer (p type GaN layer) that is doped with the acceptor type impurity. In this preferred embodiment, the acceptor type impurity is Mg (magnesium). The acceptor type impurity may instead be Zn (zinc) or other acceptor type impurity besides Mg. Also, the acceptor type impurity may be a codope of Mg and Zn.

A film thickness of the third nitride semiconductor layer 21 is preferably greater than 100 nm and is more preferably not less than 110 nm. More preferably, the film thickness of the third nitride semiconductor layer 21 is not less than 110 nm and not more than 150 nm. This is because if the film thickness of the third nitride semiconductor layer 21 is not less than 110 nm and not more than 150 nm, a maximum rated gate voltage in a positive direction can be increased. In this preferred embodiment, the film thickness of the third nitride semiconductor layer 21 is approximately 120 nm.

The third nitride semiconductor layer 21 is provided to change an energy level of a conduction band in an interface between the first nitride semiconductor layer 13 and the second nitride semiconductor layer 14 in regions directly below the gate portions 20 such that the two-dimensional electron gas 9 is not formed in the regions directly below the gate portions 20 in a state in which a gate voltage is not applied.

As shown in FIG. 2, a passivation film 15 that covers exposed surfaces of the second nitride semiconductor layer 14, the third nitride semiconductor layer 21, and the gate electrode 22 is formed on the second nitride semiconductor layer 14. Side surfaces and a front surface of the gate portion 20 are thus covered by the passivation film 15. In this preferred embodiment, the passivation film 15 is constituted of an SiN film and a film thickness thereof is approximately 50 nm to 200 nm. The passivation film 15 may instead be constituted of a single film of any one among SiN, SiO₂, and SiON or a composite film of any combination of two or more thereamong.

Source contact holes 5 and drain contact holes 6 are formed in the passivation film 15. The source contact holes 5 and the drain contact holes 6 are formed in a configuration of sandwiching the gate portions 20.

The source main electrode portion 3A of each source electrode 3 penetrates through a source contact hole 5 and contacts the second nitride semiconductor layer 14. As shown in FIG. 2, the extension portion 3B of the source electrode 3 covers gate portions 20. A recess (source electrode recess) that extends in a length direction of the source main electrode portion 3A is formed in a width intermediate portion of a front surface of the source main electrode portion 3A. Each drain electrode 4 penetrates through a drain contact hole 6 and contacts the second nitride semiconductor layer 14. A recess (drain electrode recess) that extends in a length direction of the drain electrode 4 is formed in a width intermediate portion of a front surface of the drain electrode 4.

The source electrodes 3 and the drain electrodes 4 are constituted, for example, of first metal layers (ohmic metal layers) that are in contact with the second nitride semiconductor layer 14, second metal layers (main electrode metal layers) that are laminated on the first metal layers, third metal layers (adhesion layers) that are laminated on the second metal layers, and fourth metal layers (barrier metal layers) that are laminated on the third metal layers. The first metal layers are, for example, Ti layers with thicknesses of approximately 10 nm to 20 nm. The second metal layers are, for example, AlCu layers with thicknesses of approximately 100 nm to 300 nm. The third metal layers are, for example, Ti layers with thicknesses of approximately 10 nm to 20 nm. The fourth metal layers are, for example, TiN layers with thicknesses of approximately 10 nm to 50 nm.

In the nonactive region 32, a first recess 16 that penetrates through the passivation film 15 and the second nitride semiconductor layer 14, reaches the first nitride semiconductor layer 13, and is opened at its upper surface and outer side surface (outer peripheral surface) is formed in a peripheral edge portion of the nitride semiconductor device 1. Also, a second recess 17 that penetrates through the first nitride semiconductor layer 13 and the buffer layer 12, reaches the substrate 11, and is opened at its upper surface and outer side surface (outer peripheral surface) is formed in an outer peripheral edge portion of a bottom surface of the first recess 16. A substrate contact metal (not shown) that is arranged to electrically connect the substrate 11 to the source electrodes 3 is embedded inside the first recess 16 and the second recess 17.

In this preferred embodiment, a first region 32a for directly measuring the film thickness of the second nitride semiconductor layer 14 in a manufacturing process of the nitride semiconductor device 1 is included in the nonactive region 32. In this preferred embodiment, the first region 32a is formed inside a region between a peripheral edge of the nitride semiconductor device 1 and the active region 31 in plan view. More specifically, the first region 32a, in plan view, is a region between an outer peripheral edge of the third nitride semiconductor layer 21 and the first recess 16 in FIG. 1 and FIG. 2. The first region 32a is thus adjacent to the outer peripheral edge of the third nitride semiconductor layer 21. In FIG. 1, the first region 32a is indicated by a dotted region.

The film thickness of the second nitride semiconductor layer 14 in the first region 32a differs from the film thickness of the second nitride semiconductor layer 14 in regions (hereinafter referred to as the “access regions 34”) of the active region 31 in which the ridge portions 21A, the source contact holes 5, and the drain contact holes 6 are not formed. In this preferred embodiment, the film thickness of the second nitride semiconductor layer 14 in the first region 32a is greater than the film thickness in the access regions 34. Also, the film thickness of the second nitride semiconductor layer 14 in the first region 32a may instead be less than the film thickness in the access regions 34.

With the nitride semiconductor device 1, a heterojunction is formed by there being formed on the first nitride semiconductor layer (electron transit layer) 13, the second nitride semiconductor layer (electron supply layer) 14 that differs in bandgap (Al composition). The two-dimensional electron gas 9 is thereby formed inside the first nitride semiconductor layer 13 near the interface between the first nitride semiconductor layer 13 and the second nitride semiconductor layer 14, and an HEMT making use of the two-dimensional electron gas 9 as a channel is formed. The gate main electrode portions 22A of the gate electrode 22 oppose the second nitride semiconductor layer 14 across the ridge portions 21A of the third nitride semiconductor layer 21.

Below the gate main electrode portions 22A, energy levels of the first nitride semiconductor layer 13 and the second nitride semiconductor layer 14 are pulled up by ionized acceptors contained in the ridge portions 21A that are constituted of the p type GaN layer. The energy level of the conduction band at the heterojunction interface between the first nitride semiconductor layer 13 and the second nitride semiconductor layer 14 is thus made higher than the Fermi level. Therefore, the two-dimensional electron gas 9 formed by the spontaneous polarizations of the first nitride semiconductor layer 13 and the second nitride semiconductor layer 14 and the piezo polarization due to the lattice mismatch of the two layers is not formed directly below the gate main electrode portions 22A (gate portions 20).

Therefore, when a bias is not applied to the gate electrode 22 (zero bias state), the channel due to the two-dimensional electron gas 9 is interrupted directly below the gate main electrode portions 22A. A normally-off type HEMT is thus realized. When an appropriate on voltage (for example, of 5 V) is applied to the gate electrode 22, a channel is induced inside the first nitride semiconductor layer 13 directly below each gate main electrode portion 22A and the two-dimensional electron gas 9 at both sides of the gate main electrode portion 4A becomes connected. The source and the drain are thereby made continuous to each other.

For use, for example, a predetermined voltage (for example, of 50 V to 100 V) with which the drain electrode 4 side becomes positive is applied between the source electrodes 3 and the drain electrodes 4. In this state, an off voltage (0 V) or the on voltage (5 V) is applied to the gate electrode 22 with the source electrodes 3 being at a reference potential (0 V).

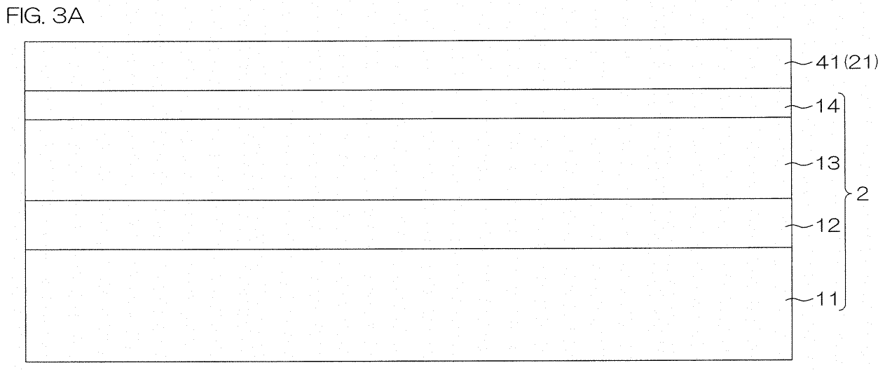

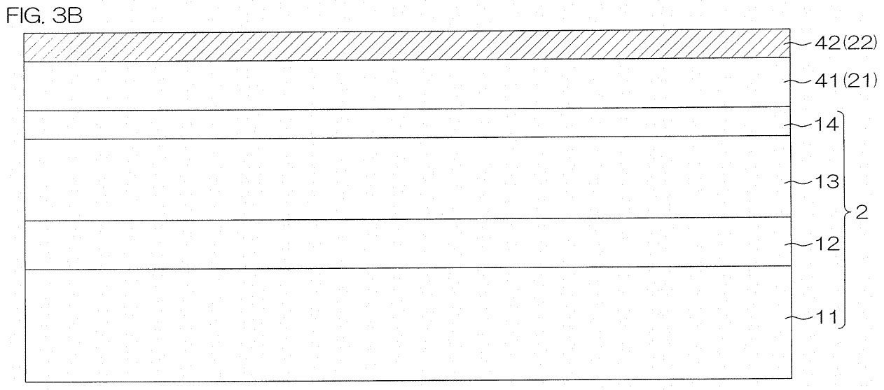

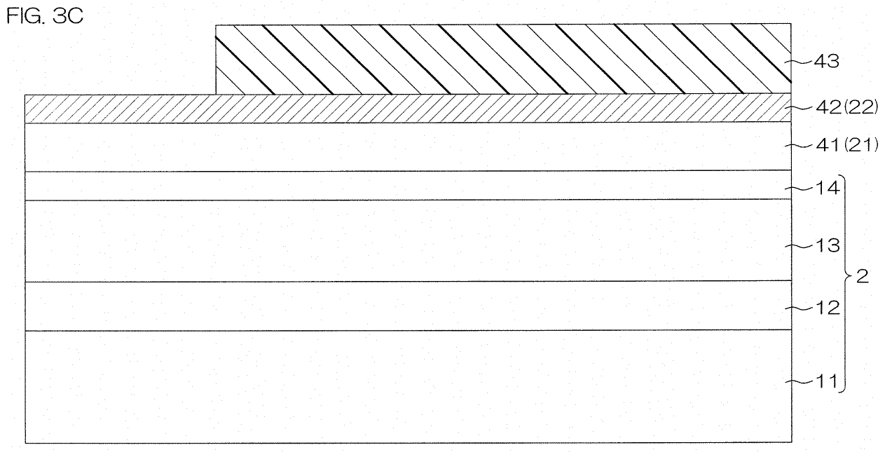

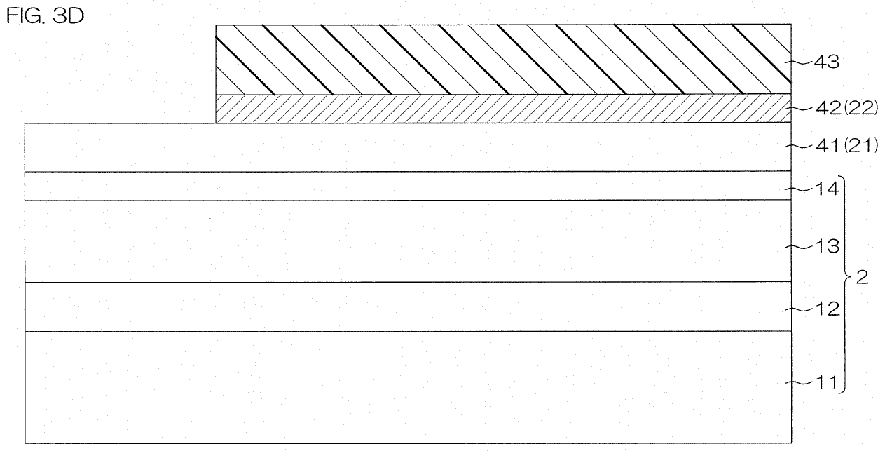

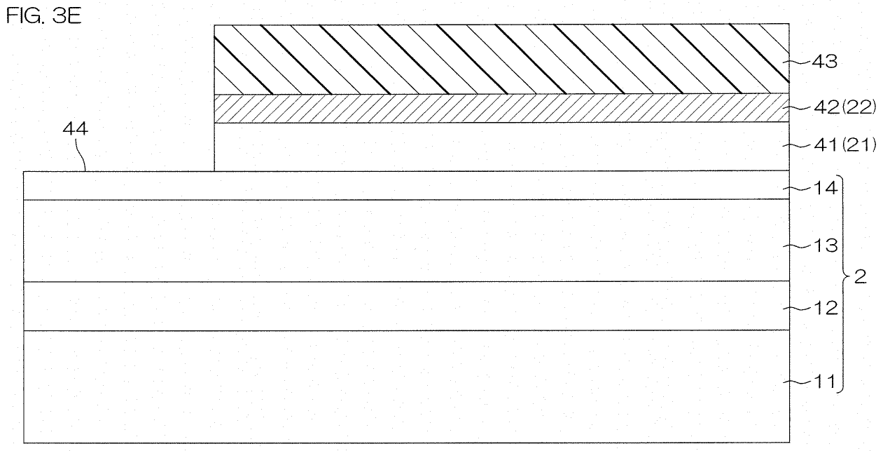

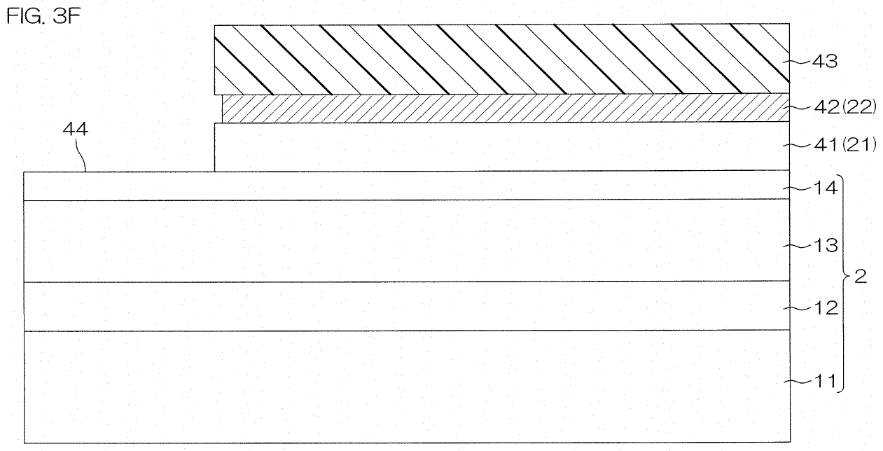

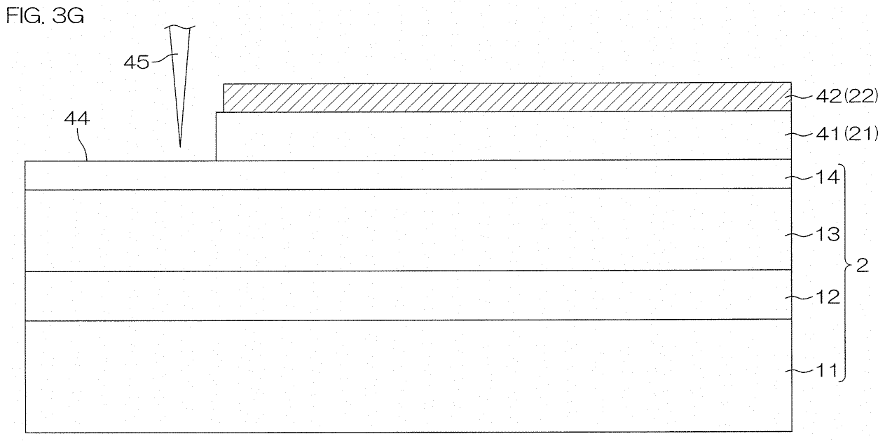

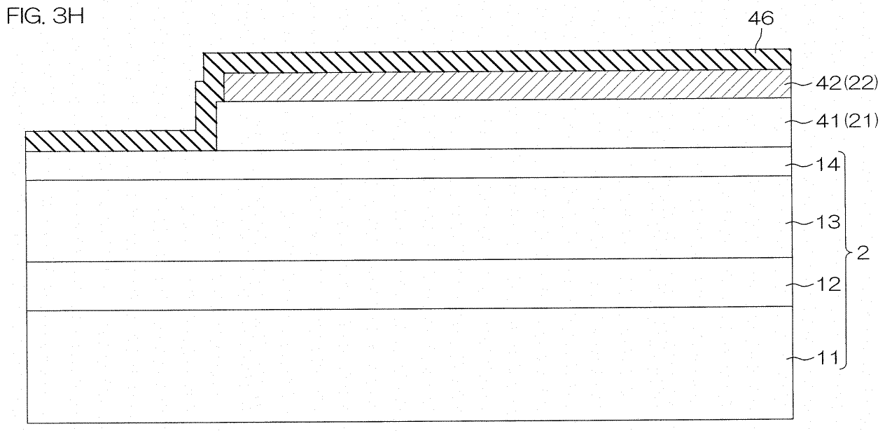

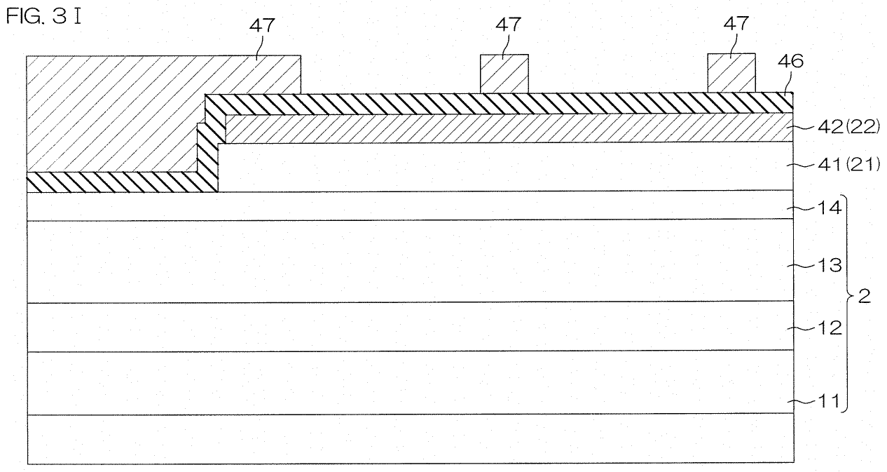

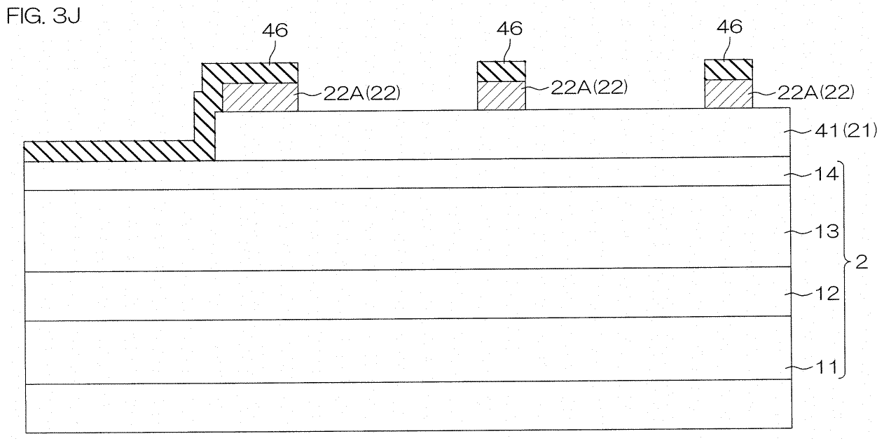

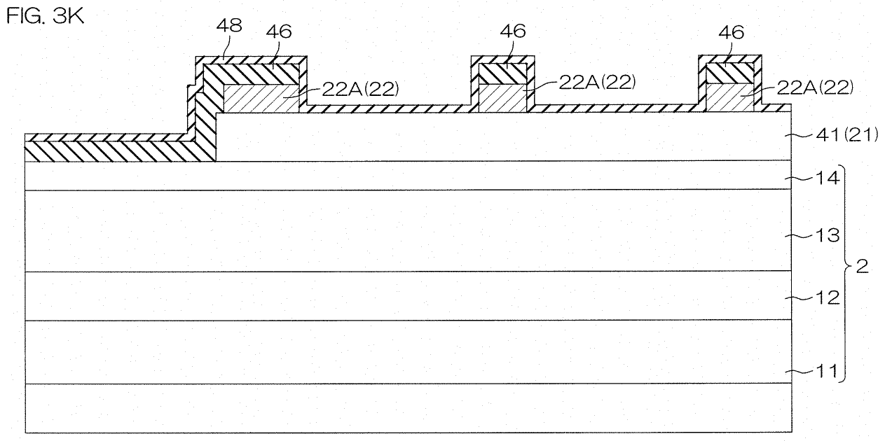

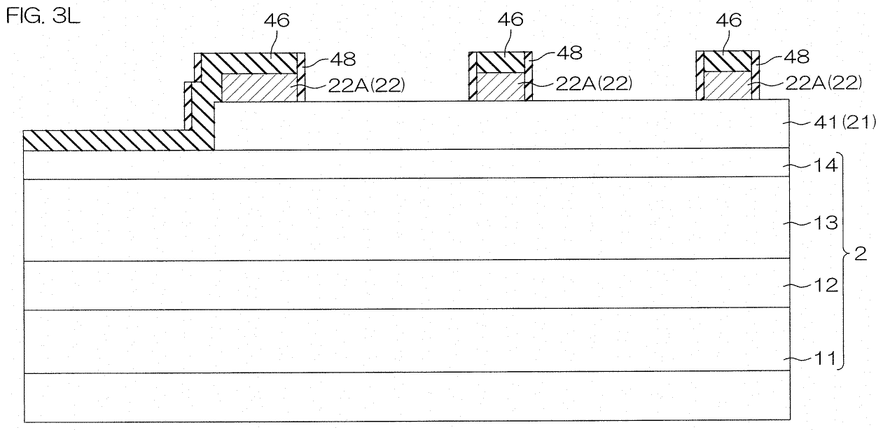

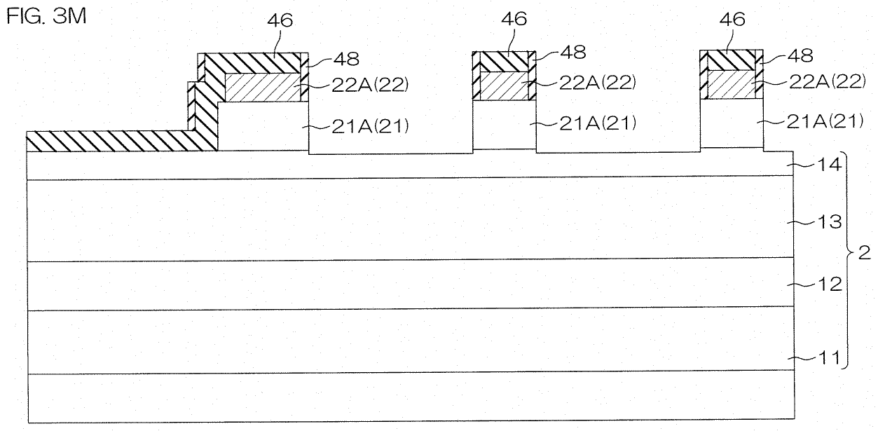

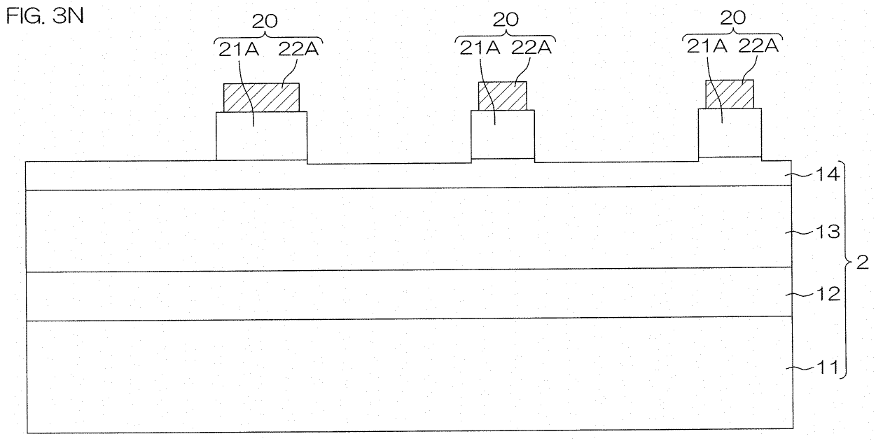

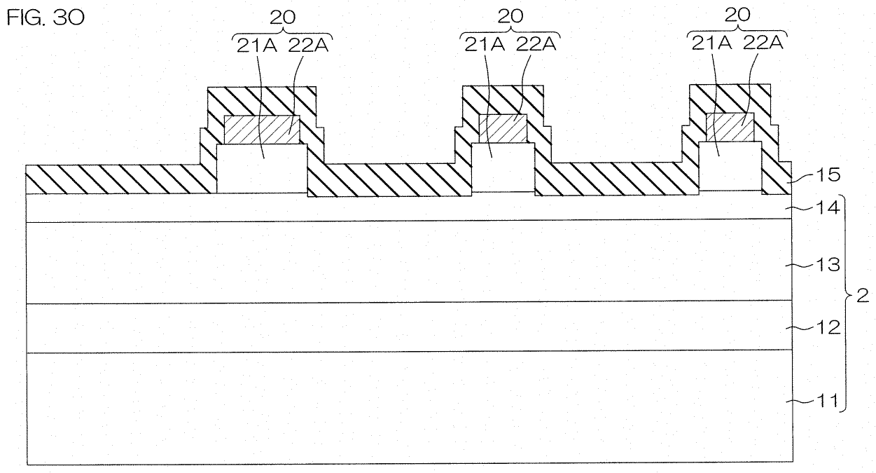

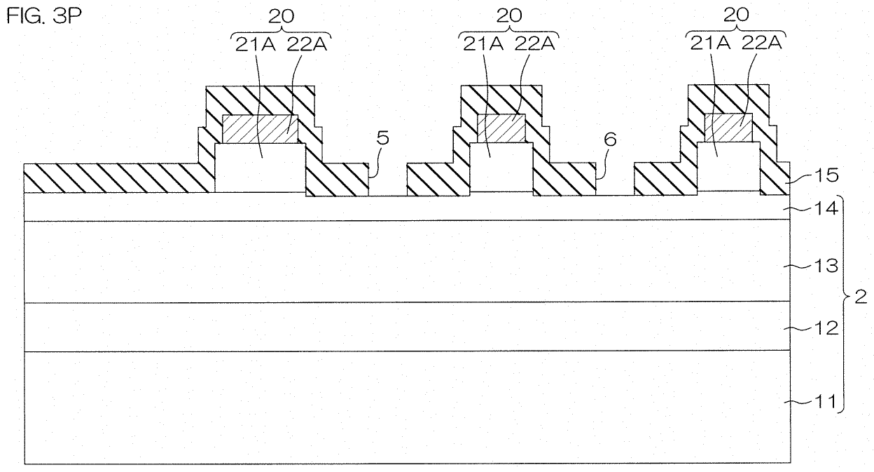

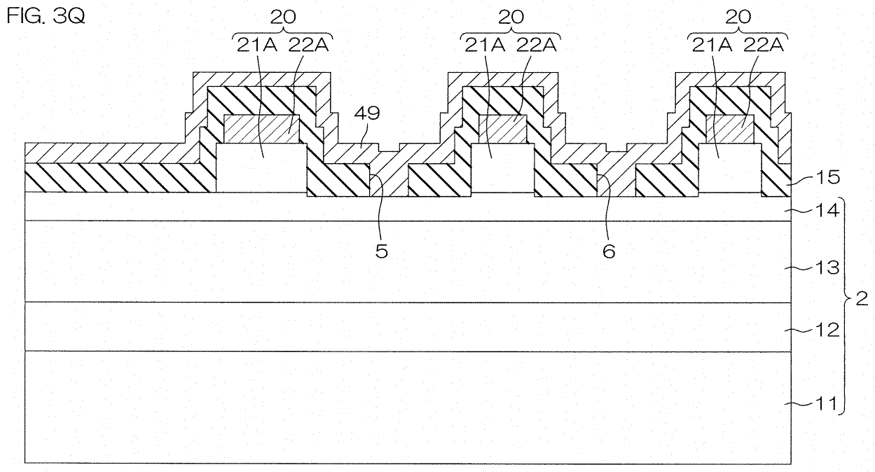

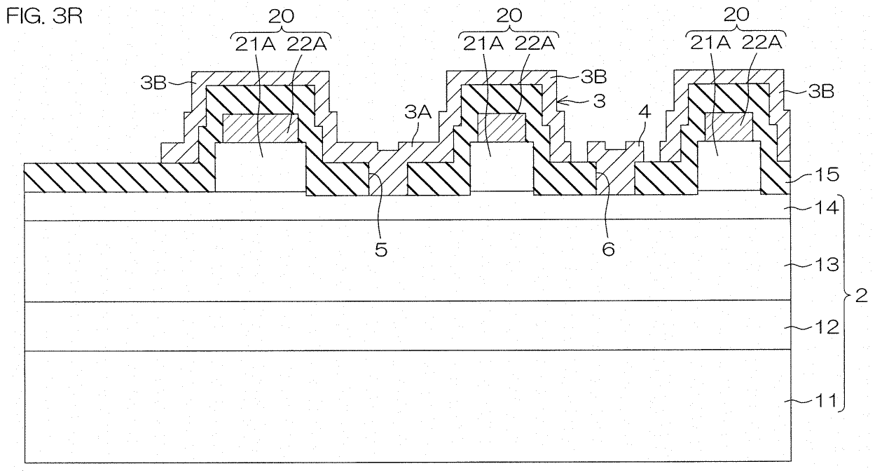

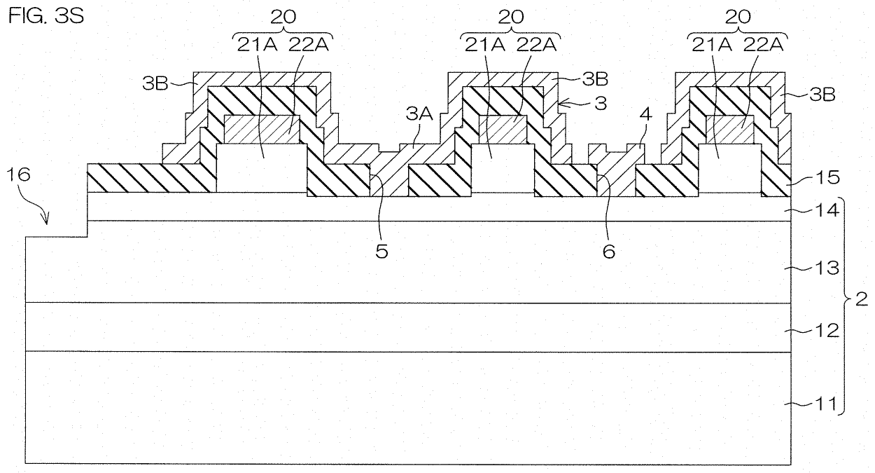

FIG. 3A to FIG. 3S are sectional views for describing an example of a manufacturing process of the nitride semiconductor device 1 described above and show a cross-sectional structure at a plurality of stages in the manufacturing process.

First, as shown in FIG. 3A, the buffer layer 12, the first nitride semiconductor layer (electron transit layer) 13, and the second nitride semiconductor layer (electron supply layer) 14 are epitaxially grown on the substrate 11 by an MOCVD (metal organic chemical vapor deposition) method. The semiconductor laminated structure 2 is thereby obtained. Further, a third semiconductor material film 41 that is a material film of the third nitride semiconductor layer 21 is epitaxially grown on the second nitride semiconductor layer 14 by the MOCVD method. In this preferred embodiment, the third semiconductor material film 41 is a p type GaN film.

Next, as shown in FIG. 3B, a gate electrode film 42 that is a material film of the gate electrode 22 is formed on the third semiconductor material film 41, for example, by a sputtering method.

Next, as shown in FIG. 3C, a resist 43 is formed on a region excluding a peripheral edge portion of the gate electrode film 42. Here, the peripheral edge portion of the gate electrode film 42 refers to a region corresponding to being further outward than the outer peripheral edge of the third nitride semiconductor layer 21 in FIG. 1 and FIG. 2.

Next, as shown in FIG. 3D, the gate electrode film 42 is etched using the resist 43 as a mask. Next, as shown in FIG. 3E, the third semiconductor material film 41 is dry-etched using the resist 43 and the gate electrode film 42 as masks. An opening region 44 that penetrates through the gate electrode film 42 and the third semiconductor material film 41 is thereby formed in the region corresponding to being further outward than the outer peripheral edge of the third nitride semiconductor layer 21 in FIG. 1 and FIG. 2.

Next, as shown in FIG. 3F, the gate electrode film 42 is isotropically etched. Thereby, a side edge at the opening region 44 side of the gate electrode film 42 is made to recede further toward an outer side of the opening region 44 than a side edge of the opening region 44 of the third semiconductor material film 41.

In the following, the etching steps of FIG. 3D to FIG. 3F (the etching steps of FIG. 3D to FIG. 3E if the etching of FIG. 3F is not performed as shall be described below) is referred to as the first etching step. Also, the step of etching TiN (the gate electrode film 42) of the first region 32a as shown in FIG. 3D is referred to as the third etching step and the step of etching p type GaN (the third semiconductor material film 41) of the first region 32a as shown in FIG. 3E is referred to as the fourth etching step.

Etching conditions of the third etching step and the fourth etching step differ. In the third etching step, for example, CF₄/Cl₂/N₂ is used as an etching gas. In the fourth etching step, for example, Cl₂/O₂/Ar is used as an etching gas. Also, in this preferred embodiment, the first etching step also serves as an alignment forming step. That is, in this preferred embodiment, an alignment mark is formed by the first etching step.

Next, as shown in FIG. 3G, the resist 43 is removed. A film thickness of the third semiconductor material film 41 is then directly measured, for example, by an AFM (atomic force microscope). In FIG. 3G, the reference sign 45 indicates an AFM probe. The film thickness of the third semiconductor material film 41 is directly measured in this manner because when the film thickness of the third semiconductor material film 41 exceeds 100 nm, it is difficult to measure the film thickness of the third semiconductor material film 41 with high precision by an ordinary indirect measurement method. Ordinary indirect measurement methods include a method of irradiating a laser onto a wafer during crystal growth and determining the film thickness from an intensity period of the reflected light, XRR (X-ray reflectivity) for thin film observation, etc.

Next, as shown in FIG. 3H, an SiN film (insulating film) 46 is formed on entire surfaces that are exposed.

Next, as shown in FIG. 3I, a resist film 47 is selectively formed on the SiN film 46 such as to cover a gate electrode preparation planned region and a region further outward than an outer peripheral edge of the gate electrode preparation planned region in plan view.

Next, as shown in FIG. 3J, the SiN film 46 and the gate electrode film 42 are patterned by dry etching using the resist film 47 as a mask. The gate electrode 22 is thereby formed. Thereafter, the resist film 47 is removed.

Next, as shown in FIG. 3K, an SiO₂ film 48 is formed, for example, by a plasma-enhanced chemical vapor deposition method (PECVD method) such as to cover entire surfaces that are exposed.

Next, as shown in FIG. 3L, the SiO₂ film 48 is etched back, for example, by dry etching such as to form the SiO₂ film 48 that covers the side surfaces of the gate electrode 22 and of the SiN film 46 thereon.

Next, as shown in FIG. 3M, the third semiconductor material film 41 is patterned by dry etching using the SiN film 46 and the SiO₂ film 48 as masks. The third nitride semiconductor layer 21 is thereby obtained.

In the following, the etching steps of FIG. 3J and FIG. 3M is referred to as the second etching step. Also, the step of etching TiN (the gate electrode film 42) of the active region 31 as shown in FIG. 3J is referred to as the fifth etching step and the step of etching p type GaN (the third semiconductor material film 41) of the active region 31 as shown in FIG. 3M is referred to as the sixth etching step. Etching conditions of the second etching step are determined based on the film thickness of the third semiconductor material film 41 that was directly measured in the step of FIG. 3G.

Etching conditions of the fifth etching step and the sixth etching step differ. In the fifth etching step, for example, CF₄/Cl₂/N₂ is used as an etching gas. In the sixth etching step, for example, Cl₂/O₂/Ar is used as an etching gas.

The etching conditions of the third etching step (see FIG. 3D) and the fifth etching step (see FIG. 3J) may be the same.

In this preferred embodiment, the etching conditions of the fourth etching step (see FIG. 3E) and the sixth etching step (see FIG. 3M) differ. Specifically, an oxygen flow rate in the fourth etching step is greater than an oxygen flow rate in the sixth etching step. The greater the oxygen flow rate, the more easily the third semiconductor material film 41 and the second nitride semiconductor layer 14 are oxidized and therefore, the slower an etching rate. An etching time of the fourth etching step (see FIG. 3E) is thus set longer than an etching time of the sixth etching step (see FIG. 3M).

An etching rate of the second nitride semiconductor layer 14 is slower than that of the third semiconductor material film 41 and the greater the oxygen flow rate, the greater a difference in etching rate between the two. Therefore, the greater the oxygen flow rate, more easily and with higher precision the third semiconductor material film 41 can be etched to a depth of a front surface of the second nitride semiconductor layer 14. The third semiconductor material film 41 can thus be etched more easily with higher precision in the fourth etching step (see FIG. 3E) than in the sixth etching step (see FIG. 3M). However, the greater the oxygen flow rate, the more easily an etched surface is roughened. Therefore, in the sixth etching step for preparing the element structure, the oxygen flow rate is lessened in comparison to the fourth etching step for preparing the first region 32a.

Since the fourth etching step and the sixth etching step are thus performed at different times and also differ in etching conditions, the film thickness of the second nitride semiconductor layer 14 in the first region 32a and the film thickness of the second nitride semiconductor layer 14 in the access region 34 differ. In this preferred embodiment, an etching amount of a surface layer portion of the second nitride semiconductor layer 14 in the sixth etching step is greater than an etching amount of the surface layer portion of the second nitride semiconductor layer 14 in the fourth etching step and therefore, the film thickness of the second nitride semiconductor layer 14 in the access region 34 is made thinner than the film thickness of the second nitride semiconductor layer 14 in the first region 32a.

However, depending on the etching conditions of the fourth etching step and the etching conditions of the sixth etching step, the film thickness of the second nitride semiconductor layer 14 in the first region 32a may become thinner than the film thickness of the second nitride semiconductor layer 14 in the access region 34.

Next, as shown in FIG. 3N, the SiN film 46 and the SiO₂ film 48 are removed by wet etching. The gate portions 20 that are constituted of the ridge portions 21A of the third nitride semiconductor layer 21 and the gate main electrode portions 22A formed on the width intermediate portions of the upper surfaces of the third nitride semiconductor layer 21 are thereby obtained.

Next, as shown in FIG. 3O, the passivation film 15 is formed such as to cover entire surfaces that are exposed. The passivation film 15 is constituted, for example, of SiN.

Next, as shown in FIG. 3P, the source contact holes 5 and the drain contact holes 6 that reach the second nitride semiconductor layer 14 are formed in the passivation film 15.

Next, as shown in FIG. 3Q, a source/drain electrode film 49 is formed such as to cover entire surfaces that are exposed.

Next, as shown in FIG. 3R, the source/drain electrode film 49 is patterned by photolithography and etching to form the source electrodes 3 and the drain electrodes 4 that are in contact with the second nitride semiconductor layer 14.

Next, as shown in FIG. 3S, the first recess 16 that reaches the first nitride semiconductor layer 13 is formed in the second nitride semiconductor layer 14 and the passivation film 15.

Lastly, the second recess 17 that reaches the substrate 11 is formed in the outer peripheral edge portion of the bottom surface of the first recess 16. The nitride semiconductor device 1 with the structure such as shown in FIG. 1 and FIG. 2 is thereby obtained.

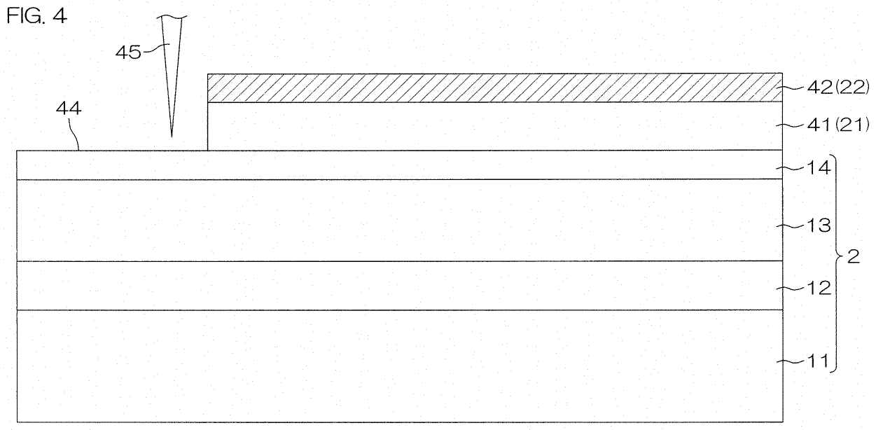

With the above-described manufacturing method, after the step of FIG. 3E, the side edge at the opening region 44 side of the gate electrode film 42 is made to recede further toward the outer side of the opening region 44 than the side edge at the opening region 44 side of the third semiconductor material film 41 in the etching step of FIG. 3F. However, after the step of FIG. 3E, the film thickness of the third semiconductor material film 41 may be arranged to be measured after removing the resist 43 on the gate electrode film 42 as shown in FIG. 4. Specifically, for example, a sum d3 of a film thickness d1 of the gate electrode film 42 and a film thickness d2 of the third semiconductor material film 41 is directly measured by the AFM. Also, the film thickness d1 of the gate electrode film 42 is measured by an ordinary indirect measurement method. The film thickness d2 of the third semiconductor material film 41 is then determined by calculating (d3-d1).

If the step of FIG. 4 is performed after performing the step of FIG. 3E, transition to the step of FIG. 3H should be performed after the step of FIG. 4.

By the preferred embodiment described above, it is made possible to directly measure the film thickness of the material film (third semiconductor material film 41) of the third nitride semiconductor layer 21 before forming the ridge portions 21A of the third nitride semiconductor layer 21. It is thereby made possible to appropriately determine the etching conditions for forming the ridge portions 21A of the third nitride semiconductor layer 21.

Therefore, the present preferred embodiment is especially effective for making the film thickness of the third nitride semiconductor layer 21 thicker than 100 nm to increase the maximum rated gate voltage in the positive direction.

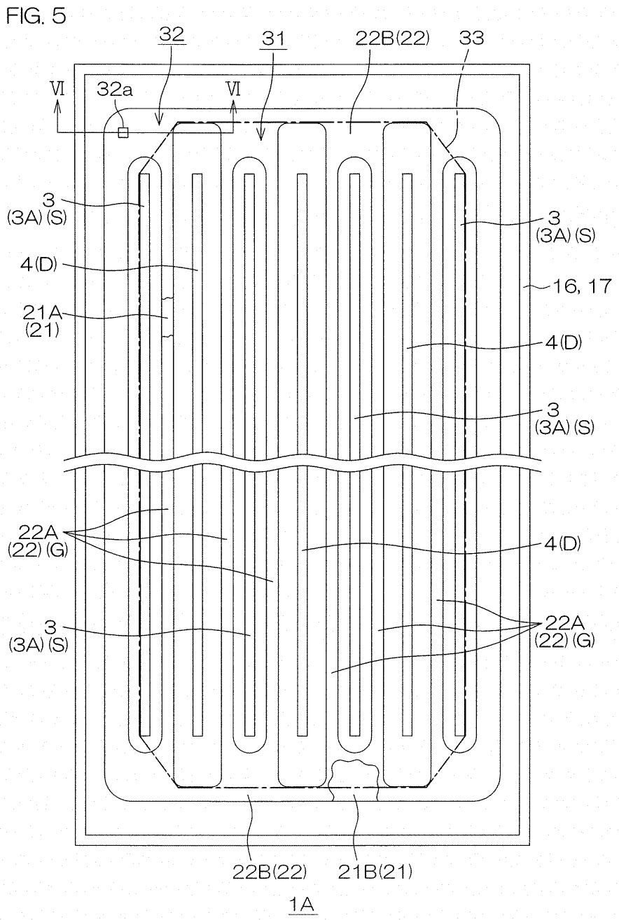

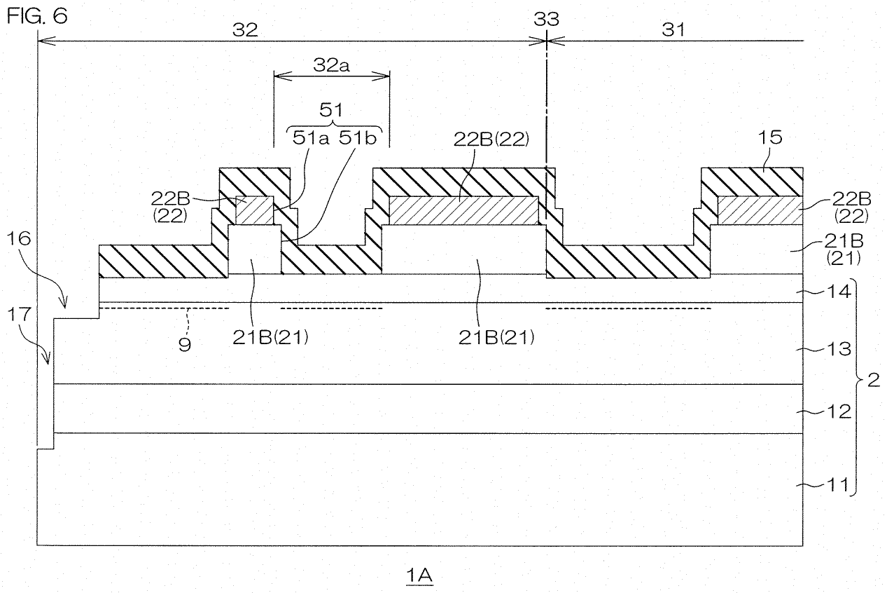

FIG. 5 is a sectional view for describing the arrangement of a nitride semiconductor device according to a second preferred embodiment of the present invention. FIG. 6 is an enlarged sectional view taken along line VI-VI of FIG. 5. In FIG. 5, portions corresponding to respective portions in FIG. 1 described above are indicated with the same reference signs attached as in FIG. 1. In FIG. 6, portions corresponding to respective portions in FIG. 2 described above are indicated with the same reference signs attached as in FIG. 2.

However, in FIG. 5, the passivation film 15 (see FIG. 6) is omitted for convenience of description. Also, as with the first preferred embodiment, just the source main electrode portion 3A is illustrated for each source electrode 3 and the extension portion 3B is omitted in FIG. 5. Also, as with the first preferred embodiment, although the width of each ridge portion 21A of the third nitride semiconductor layer 21 is greater than the width of each gate main electrode portion 22A of the gate electrode 22 as shall be described below, the width of each ridge portion 21A is illustrated as being equal to the width of each gate main electrode portion 22A in FIG. 5.

In comparison to the nitride semiconductor device 1 according to the first preferred embodiment, the nitride semiconductor device 1A according to the second preferred embodiment differs in the first region 32a that is formed inside the nonactive region 32.

With the second preferred embodiment, the first region 32a is formed inside a coupling portion 21B of the third nitride semiconductor layer 21. More specifically, as shown in FIG. 5, the first region 32a of a rectangular shape in plan view is formed at a position of the coupling portion 21B of the third nitride semiconductor layer 21 that is close to an upper left corner of the third nitride semiconductor layer 21. The coupling portion 21B of the third nitride semiconductor layer 21 is an example of “an extension region that extends from an end of a ridge portion” of the present invention.

As shown in FIG. 6, an opening portion 51 of quadrilateral shape in plan view that penetrates through the base portion 22B of the gate electrode 22 and the coupling portion 21B of the third nitride semiconductor layer 21 and reaches the second nitride semiconductor layer 14 is formed in the first region 32a. The opening portion 51 is constituted of a first opening portion 51a of quadrilateral shape in plan view that penetrates through the base portion 22B of the gate electrode 22 and a second opening portion 51b of quadrilateral shape in plan view that is in communication with the first opening portion 51a and penetrates through the coupling portion 21B of the third nitride semiconductor layer 21. The first region 32a is thus adjacent to the third nitride semiconductor layer 21.

In plan view, the first opening portion 51a is larger than the second opening portion 51b and four sides of the first opening portion 51a are respectively parallel to four sides of the second opening portion 51b. Also, in plan view, the second opening portion 51b is positioned at a center of the first opening portion 51a. A peripheral edge of the gate electrode 22 along the opening portion 51 (first opening portion 51a) is thus receded toward an outer side of the opening portion 51 with respect to a peripheral edge of the third nitride semiconductor layer 21 along the opening portion 51 (second opening portion 51b).

A method for manufacturing the nitride semiconductor device 1A shall now be described. Even in the method for manufacturing the nitride semiconductor device 1A, the step of FIG. 3A and the step of FIG. 3B described above are the same. When the step of FIG. 3B ends, the opening portion 51 that penetrates through the gate electrode film 42 and the third semiconductor material film 41 is formed by photolithography and etching. The film thickness of the third semiconductor material film 41 is then directly measured, for example, by the AFM.

Thereafter, the same steps as those of FIG. 3H to FIG. 3S are performed. However, in manufacturing the nitride semiconductor device 1A, in the step of FIG. 3I, although a region of the SiN film 46 front surface that corresponds to the gate electrode preparation planned region is covered by the resist film 47, the region further outward than the outer peripheral edge of the gate electrode preparation planned region is not covered by the resist film 47. The gate electrode film 42 in the region further outward than the outer peripheral edge of the gate electrode preparation planned region and the third semiconductor material film 41 in a region further outward than an outer peripheral edge of a third nitride semiconductor layer preparation planned region are thus etched (removed) by the steps of FIG. 3I to FIG. 3N.

When the step of FIG. 3S ends, the second recess 17 that reaches the substrate 11 is formed in the outer peripheral edge portion of the bottom surface of the first recess 16. The nitride semiconductor device 1A with the structure such as shown in FIG. 5 and FIG. 6 is thereby obtained.

The same effects as the first preferred embodiment can also be obtained with the second preferred embodiment.

Although the first and second preferred embodiments of the present invention have been described above, the present invention can be implemented in yet other preferred embodiments.

For example, Si may be contained in the second nitride semiconductor layer 14 directly below the source electrodes 3 and the drain electrodes 4.

Also, although with the preferred embodiments described above, silicon was taken up as an example of the material of the substrate 11, any substrate material besides this, such as a sapphire substrate, a QST substrate, etc., may be applied.

While preferred embodiments of the present invention were described in detail above, these are merely specific examples used to clarify the technical contents of the present invention and the present invention should not be interpreted as being limited to these specific examples and the scope of the present invention is limited only by the appended claims.

The present application corresponds to Japanese Patent Application No. 2020-011740 filed on Jan. 28, 2020 in the Japan Patent Office, and the entire disclosure of this application is incorporated herein by reference.

### REFERENCE SIGNS LIST

1 nitride semiconductor device
2 semiconductor laminated structure
3 source electrode
3A source main electrode portion
3B extension portion
4 drain electrode
5 source contact hole
6 drain contact hole
9 two-dimensional electron gas
11 substrate
12 buffer layer
13 first nitride semiconductor layer (electron transit layer)
14 second nitride semiconductor layer (electron supply layer)
15 passivation film
16 first recess
17 second recess
20 gate portion
21 third nitride semiconductor layer (semiconductor gate layer)
21A ridge portion
21B coupling portion
22 gate electrode
22A gate main electrode portion
22B base portion
31 active region
32 nonactive region
32a first region
33 boundary
41 third semiconductor material film
42 gate electrode film
43 resist
44 opening region
45 AFC probe
46 SiN film
47 resist film
48 SiO₂ film
49 source/drain electrode film
51 opening portion
51a first opening portion
51b second opening portion

1. A nitride semiconductor device comprising:
a substrate;
a first nitride semiconductor layer that is disposed above the substrate and constitutes an electron transit layer;
a second nitride semiconductor layer that is formed on the first nitride semiconductor layer and constitutes an electron supply layer;
a third nitride semiconductor layer that is disposed on the second nitride semiconductor layer, has a ridge portion at least at a portion thereof, and contains an acceptor type impurity;
a gate electrode that is disposed on the ridge portion; and
a source electrode and a drain electrode that, on the second nitride semiconductor layer, are disposed across the ridge portion from each other; and
having, in plan view, an active region that contributes to a transistor operation and a nonactive region that does not contribute to the transistor operation, and
wherein the nonactive region has a first region and
a film thickness of the second nitride semiconductor layer in the first region differs from a film thickness of the second nitride semiconductor layer in a region of the active region in which the ridge portion, the source electrode, and the drain electrode are not formed.

2. The nitride semiconductor device according to claim 1, wherein the film thickness of the second nitride semiconductor layer in the first region is thicker than the film thickness of the second nitride semiconductor layer in the region of the active region in which the ridge portion, the source electrode, and the drain electrode are not formed.

3. The nitride semiconductor device according to claim 1, wherein the film thickness of the second nitride semiconductor layer in the first region is thinner than the film thickness of the second nitride semiconductor layer in the region of the active region in which the ridge portion, the source electrode, and the drain electrode are not formed.

4. The nitride semiconductor device according to claim 1, wherein the first region is adjacent to the third nitride semiconductor layer.

5. The nitride semiconductor device according to claim 1, wherein the nitride semiconductor device has a quadrilateral shape in plan view and
the first region is present between a peripheral edge of the nitride semiconductor device and the active region in plan view.

6. The nitride semiconductor device according to claim 1, wherein the third nitride semiconductor layer has an extension region that extends from an end of the ridge portion,
an opening portion that penetrates through the gate electrode and the third nitride semiconductor layer and reaches the second nitride semiconductor layer is formed inside the extension region within the nonactive region, and
the first region is, in plan view, a region in which the opening portion is formed.

7. The nitride semiconductor device according to claim 1, wherein, in plan view, a side edge at the first region side of the gate electrode on the ridge portion adjacent to the first region is receded further inward than aside edge at the first region side of an upper surface of the ridge portion.

8. The nitride semiconductor device according to claim 1, wherein a passivation film that covers exposed surfaces of the second nitride semiconductor layer, the third nitride semiconductor layer, and the gate electrode is formed on the second nitride semiconductor layer,
a source contact hole and a drain contact hole are formed in the passivation film,
the source electrode penetrates through the source contact hole and contacts the second nitride semiconductor layer, and
the drain electrode penetrates through the drain contact hole and contacts the second nitride semiconductor layer.

9. The nitride semiconductor device according to claim 8, wherein the source electrode has a source main electrode portion that penetrates through the source contact hole and contacts the second nitride semiconductor layer and an extension portion that extends from the source main electrode portion and covers the gate electrode adjacent thereto.

10. The nitride semiconductor device according to claim 9, wherein the source main electrode portion extends in parallel to the ridge portion and a source electrode recess that extends in a length direction of the source main electrode portion is formed in a width intermediate portion of a front surface of the source main electrode portion.

11. The nitride semiconductor device according to claim 8, wherein the drain electrode extends in parallel to the ridge portion and a drain electrode recess that extends in a length direction of the drain electrode is formed in a width intermediate portion of a front surface of the drain electrode.

12. The nitride semiconductor device according to claim 8, wherein a first recess that penetrates through the passivation film and the second nitride semiconductor layer, reaches the first nitride semiconductor layer, and is opened at its upper surface and outer side surface is formed in a peripheral edge portion of the nitride semiconductor device and
a second recess that penetrates through the first nitride semiconductor layer, reaches the substrate, and is opened at its upper surface and outer side surface is formed in an outer peripheral edge portion of a bottom surface of the first recess.

13. The nitride semiconductor device according to claim 1, wherein a film thickness of the third nitride semiconductor layer is greater than 100 nm.

14. The nitride semiconductor device according to claim 1, wherein the gate electrode is constituted of a single film of any one among TiN, TiW, Ti, and W or a composite film of any combination of two or more thereamong.

15. The nitride semiconductor device according to claim 1, wherein the second nitride semiconductor layer is constituted of an Alₓ₁Ga₁₋ₓ₁N (0<x1<1) layer and
the second nitride semiconductor layer is constituted of a GaN layer.

16. The nitride semiconductor device according to claim 1, wherein the acceptor impurity is Mg, Zn, or a codope thereof.

17. A method for manufacturing nitride semiconductor device comprising:
a step of preparing a nitride semiconductor laminated structure that includes a substrate, a first nitride semiconductor layer disposed above the substrate and constituting an electron transit layer, a second nitride semiconductor layer formed on the first nitride semiconductor layer and constituting an electron supply layer, and a third nitride semiconductor layer disposed on the second nitride semiconductor layer and containing an acceptor type impurity;
a step of forming a gate electrode film on the nitride semiconductor laminated structure;
a first etching step of selectively etching the gate electrode film and the third nitride semiconductor layer to form an opening region that penetrates through the gate electrode film and the third nitride semiconductor layer and reaches the second nitride semiconductor layer; and
a second etching step of selectively etching the gate electrode film and the third nitride semiconductor layer after the first etching step to form a gate electrode portion of a ridge shape on the second nitride semiconductor layer; and
wherein etching conditions of the first etching step and the second etching step differ.

18. The method for manufacturing nitride semiconductor device according to claim 17, wherein a film thickness of the third nitride semiconductor layer is measured using the opening region and the etching condition of the second etching step is determined based on the measurement result.

19. The method for manufacturing nitride semiconductor device according to claim 17 wherein the first etching step also serves as an alignment forming step.

20. The method for manufacturing nitride semiconductor device according to claim 17, wherein the first etching step is constituted of a third etching step of etching the gate electrode film and a fourth etching step of etching the third nitride semiconductor layer,
the second etching step is constituted of a fifth etching step of etching the gate electrode film and a sixth etching step of etching the third nitride semiconductor layer,
etching conditions of the third etching step and the fourth etching step differ mutually, and
etching conditions of the fifth etching step and the sixth etching step differ mutually.

21. The method for manufacturing nitride semiconductor device according to claim 20, wherein the etching conditions of the fourth etching step and the sixth etching step differ mutually.

22. The method for manufacturing nitride semiconductor device according to claim 21, wherein the etching conditions of the third etching step and the fifth etching step are the same.

23. The method for manufacturing nitride semiconductor device according to claim 17, wherein the first etching step has a step for making a peripheral edge of the gate electrode film along the opening region recede further toward an outer side of the opening region than a peripheral edge of the third nitride semiconductor layer along the opening region.

24. The method for manufacturing nitride semiconductor device according to claim 17, wherein, in the first etching step, the opening region is formed in an entirety of a peripheral edge portion of the gate electrode film.

25. The method for manufacturing nitride semiconductor device according to claim 24, comprising, between the first etching step and the second etching step:
a step of forming an insulating film on an entire surface after a film thickness measurement of the third nitride semiconductor layer using the opening region has been performed; and
a step of selectively forming a resist film on the insulating film such as to cover a gate electrode preparation planned region and a region further outward than the gate electrode preparation planned region in plan view.

26. The method for manufacturing nitride semiconductor device according to claim 17, wherein the gate electrode film has a quadrilateral shape in plan view and,
in the first etching step, the opening region is formed at a position close to a corner of the gate electrode film.

27. The method for manufacturing nitride semiconductor device according to claim 26, comprising, between the first etching step and the second etching step:
a step of forming an insulating film on an entire surface after a film thickness measurement of the third nitride semiconductor layer using the opening region has been performed; and
a step of selectively forming a resist film on the insulating film such as to cover a gate electrode preparation planned region in plan view.
